(19) United States
(12) Patent Application Publication
(10) Pub. No.: US 2026/0141974 A1
(43) Pub. Date: May 21, 2026

(54) READ LEVEL ADJUSTMENT FOR MEMORY DEVICE

(71) Applicant: MICRON TECHNOLOGY, INC., BOISE, ID (US)

(72) Inventors: ZHENLEI SHEN, Milpitas, CA (US); AARON LEE, Sunnyvale, CA (US); YANG LIU, Melissa, TX (US); JIANGLI ZHU, San Jose, CA (US)

(21) Appl. No.: 19/095,735

(22) Filed: Mar. 31, 2025

Related U.S. Application Data
(60) Provisional application No. 63/722,370, filed on Nov. 19, 2024.

(51) Int. Cl. G11C 29/52; G11C 16/08; G11C 16/26; G11C 29/02

(52) U.S. Cl. CPC G11C 29/52; G11C 16/08; G11C 16/26; G11C 29/028

(57) ABSTRACT

A technique is disclosed for calibration of read voltages in a memory device. In some instances, a controller, measures a read level corresponding to a predetermined voltage applied to an array of the memory device. The controller computes a rolling average read level measurement based on the read level and a previously computed rolling average read level measurement. The controller assigns the array to a respective bin of bins to identify one or more read voltages for use by the controller to read data from the array. The controller can record the computed rolling average read level measurement in memory for use in a subsequent rolling average read level measurement computation to replace the previously computed rolling average read level measurement.

### RELATED APPLICATIONS

This application claims priority from U.S. Patent Application Ser. No. 63/722,370, filed 19 Nov. 2024, which is incorporated herein in its entirety.

### TECHNICAL FIELD

This disclosure relates to adjusting read levels in a memory device.

### BACKGROUND

A memory sub-system includes a memory device designed for data storage. These memory devices are implemented as non-volatile and volatile memory devices in various examples. In some such examples, a host system employs a memory sub-system for the purposes of storing data on the memory devices and for retrieving data from the memory devices. Not-AND (NAND) flash memory is a type of non-volatile storage technology used in electronic devices and computers for data storage. In NAND flash memory, data is stored in memory cells that can hold electrical charges, representing data bits.

A read level in a memory device refers to a specific voltage applied to memory cells during a read operation to determine the stored data. The voltage applied is used to identify a logic state (e.g., “0” or “1”) stored in a cell by detecting how much charge the cell holds. Applying incorrect voltages can result in misreads, where the stored data is either under-read or over-read.

### BRIEF DESCRIPTION OF THE DRAWINGS

FIG. 1 illustrates an example computing system that includes a memory subsystem in accordance with some examples of the present disclosure.

FIG. 2 illustrates an error corrector of a memory sub-system of the computing system of FIG. 1.

FIG. 3A illustrates an example of a read level response graph without read level shift.

FIG. 3B illustrates an example of a read level response graph with read level shift.

FIG. 4 illustrates an example of a bin assignment graph.

FIG. 5 illustrates a flowchart of an example method for read level tracking.

FIG. 6 illustrates an example of a computer system (a machine) in which examples of the present description may operate.

### DETAILED DESCRIPTION

This description relates to read level calibration using rolling average read level tracking of a memory device. Read level tracking refers to a process of monitoring read levels of the memory device so that correct read voltages can be applied to an array of memory cells (referred to herein as “array”) during data retrieval operations (e.g., read operations) in memory devices (e.g., Not-AND (NAND) memory devices). Proper read voltages are needed so that data stored in the array can be correctly interpreted (read). Each memory cell of the array can store different charge levels corresponding to different logic states, and different read voltages can be used to determine which logic state a memory cell is storing during a read operation of the array.

Prior read level tracking techniques use an instantaneous read level measurement for bin assignment (e.g., adjusting read voltages that are used in read operations), which are susceptible to external factors, such as noise and variations (e.g., temperature variations). The external factors influence the memory device's performance characteristics and cause the read level to shift non-linearly, which can result in improper bin assignment, leading to incorrect data readings.

A rolling average read level tracking technique is described herein that uses an average instantaneous read level measurement for bin assignment. The rolling average instantaneous read level measurement is computed based on one or more previous (prior) rolling average instantaneous level measurements and a current instantaneous read level measurement. The rolling average instantaneous read level measurement curtails noise and variations (the external factors), in some instances, reducing biasing from these factors. The employment of the rolling average instantaneous read level measurement allows for a robust and accurate read level bin assignment and thus improved read level calibration over time.

A memory sub-system refers to a storage device, a memory module or some combination thereof. The memory sub-system includes a memory device or multiple memory devices that store data. The memory devices could be volatile or non-volatile devices. Some examples of a memory sub-system include high density non-volatile memory devices where retention of data is desired during intervals of time where no power is supplied to the memory device. One example of non-volatile memory devices is a NAND memory device. A non-volatile memory device is a package that includes a die(s). Each such die can include a plane(s).

For some types of non-volatile memory devices (e.g., NAND memory devices), each plane includes a set of physical blocks and each physical block includes a set of pages. Each page includes a set of memory cells, which are commonly referred to as cells. A cell is an electronic circuit that stores information. A cell stores at least one bit of binary information and has various logic states that correlate to the number of bits being stored. The logic states are represented by binary values, such as “0” and “1”, or as combinations of such values, such as “00”, “01”, “10” and “11”.

A memory device includes multiple cells arranged in a two-dimensional or a three-dimensional grid. In some examples, memory cells are formed on a silicon wafer in an array of columns connected by conductive lines (also referred to as bitlines, or BLs) and rows connected by conductive lines (also referred to as wordlines or WLs). A wordline has a row of associated memory cells in a memory device that are used with a bitline or multiple bitlines to generate the address of each of the memory cells. The intersection of a bitline and a wordline defines an address of a given memory cell.

A block refers to a unit of the memory device used to store data. In various examples, the unit could be implemented as a group of memory cells, a wordline group, a wordline or as individual memory cells. Multiple blocks are grouped together to form separate partitions (e.g., planes) of the memory device to enable concurrent operations to take place on each plane. A solid-state drive (SSD) is an example of a memory sub-system that includes a non-volatile memory device(s) and a memory sub-system controller (referred to here as a controller) to manage the non-volatile memory devices.

The controller is configured/programmed to encode the host and other data, as part of a write operation, into a format for storage at the memory device(s). Encoding refers to a process of generating parity bits from embedded data (e.g., a sequence of binary bits) using an error correction code (ECC) and combining the parity bits to the embedded data to generate a Low Density Parity Check (LDPC) codeword. LDPC encoding refers to an encoding method that utilizes an LDPC code to generate the parity bits, which can be referred to as a parity codeword. User data (e.g., embedded data) is combined with the parity codeword to form the LDPC codeword, which may alternatively be referred to simply as a codeword. The LDPC codeword is storable at the memory device(s) of the memory sub-system.

In large-scale data storage devices, such as NAND memory devices, data can be stored randomly in the array. This randomness in data storage leads to an approximately uniform distribution of logic states that can be stored in the array. In some examples, the controller writes data (e.g., the codeword) to the array so that a reliability and lifespan of the array is optimized. The data (e.g., different logic states) written to the array can be about evenly distributed so that a wear and tear on the memory cells of the array is distributed. In some instances, the controller can use ECC to spread the data out across the array so that the data is randomly stored in the memory devices and provides an even distribution of logic states. As an example, if an ECC employs a balanced code or randomizes data placement to curtail wear and tune read/write cycles this can result in an approximately uniform logic state distribution across the array.

In memory devices, such as NAND memory devices, data (e.g., the codeword) can be stored in the array as different charge levels. These charge levels can correspond to different bit values (e.g., one or more bits of 0 or 1's) of the codeword that can be stored. Each memory cell of the array can be a single-level cell (SLC) or a higher-order cell, which can store multiple bits per cell. Example higher-order cells (e.g., multi-bit memory cells) can include multi-level cells (MLCs), TLCs, quad-level cells (QLCs) and penta-level cells (PLC's) or higher-level cells.

In some examples, the memory devices can include one or more arrays of memory cells such as SLCs, MLCs, TLCs, QLCs or some combination thereof, wherein each array can be connected to a wordline. In some examples, a particular memory device can include an SLC portion, an MLC portion, a TLC portion and/or a QLC portion of memory cells. Each logic state stored by each memory cell (as a charge level) can have an equal probability of being used in the array during data writing (a write operation).

By way of example, if 180,000 TLCs are used and the data written to these cells is random, then statistically, each of the eight possible states should occur approximately at a same frequency over such a large number of data cells in the array. Thus, in a sufficiently large sample of cells, such as 180,000 TLCs, each logic state (e.g., 000 to 111) can be represented about equally in the array.

In some examples, the controller can decode codewords, as part of a read operation, stored at the memory device(s) of the memory sub-system. Decoding refers to a process of reconstructing the original user data (e.g., sequence of binary bits embedded in the codeword) from the codeword received from storage at the memory device(s). LDPC decoding refers to a decoding method that utilizes the LDPC code to reconstruct the original user data (embedded data).

To interpret the data correctly stored in the array, a read voltage is applied to the array. The read voltage is a specific voltage level (or amount of voltage) that can be provided to the array to interpret (read) stored charges therein corresponding to reading the codeword. The read voltage can be applied during a read operation. Each stored charge can represent one or more bits of the data (e.g., the codeword) corresponding to a logic state. A logic state in a basic configuration can represent a single bit (e.g., a “0” or “1”). However, in higher-order cells, the logic state can be represented by a combination of several bits. Thus, the read voltage used to read the codeword determines how a charge in a cell can be interpreted in the array.

For example, during the read operation, the controller applies a read voltage to a wordline to which the array can be coupled. Each cell of the array connected to the wordline can be accessed or manipulated based on the read voltage. The logic state in each memory cell can depend on an amount of electrical charge (the stored charge) programmed into a cell's gate (e.g., a floating gate). Each level of charge in a cell can correspond to different logic states, which can represent multiple bits in higher-order cell configurations. To write data to the array, a charge level (an amount of stored charge) within the cells of the array can be altered to reflect a desired logic state.

An amount of electrical charge (e.g., a number of electrons) in a gate influences a voltage threshold of the cell. The voltage threshold of a memory cell refers to a minimum voltage needed to cause the cell to conduct electricity and indicates a charge level that corresponds to specific data (logic state). The read voltage is the voltage applied to the array during the read operation to determine which logic states are stored in the array based on how the cell responds, which indicates whether the cell conducts electricity at that voltage.

For example, when reading word level data, the controller applies a set of read voltages to the wordline to determine stored logic states corresponding to reading the wordline. The term “set,” as used herein, may refer to either a single instance of an object or multiple instances of an object, for example, a read voltage. The controller can sequentially apply increasing levels of read voltages from the set of read voltages to the wordline to determine all possible stored logic states stored in the array and thus read the stored data (the codeword). In higher-order cells, multiple read voltages are needed to determine a stored logic state. For example, if the array includes TLCs, multiple read voltages can be used to read the array.

Applying an incorrect read voltage to the wordline and thus to the array can result in a misread of the stored charge and thus the stored logic state. For example, if the read voltage is too low, the read voltage might not reach a threshold needed to activate one or more cells of the array that holds a higher charge. This scenario can lead to under-reading, where a cell's state is read as being lower than an actual cell state (e.g., reading 001 instead of 011). In some examples, if the read voltage is too high, the read voltage can surpass the required threshold for a lower charge state and wrongly trigger the one or more cells with higher charge states.

Accordingly, applying an incorrect read voltage leads to errors in data interpretation. Misreads in memory cells (or the array) can be caused by changes in performance characteristics of the memory device, which can be caused by degradation. Degradation can refer to a wear and tear of a memory device (e.g., cells). Memory device performance is influenced by changes in cell attributes (or characteristics) over time. Cell changes can include shifts in cell threshold voltages from aging and wear and tear, for example, from repeated write and/or delete cycles, which affect how cells respond to applied read voltages.

To curtail misreads, the controller calibrates (adjusts) the read voltages over time so that the data from the array can be interpreted (read) correctly, such as during the read operation. Calibration involves adjusting the read voltages based on an ongoing assessment of memory device behavior (e.g., cell or array behavior). For example, the controller can enter a calibration mode to implement a calibration operation. The calibration operation can be implemented periodically as the memory device operates.

As the memory cells degrade corresponding threshold voltages, that is, a voltage at which the one or more cells of the array begin to conduct changes. This change means that the voltage levels originally set to read the logic states may no longer trigger the correct response from the cells (the array). The controller executes the calibration operation to periodically check how the array respond to these set read voltages. If the controller determines that the array does not activate or conduct electricity at the expected voltages this is an indication that the threshold voltages have shifted.

The controller executes the calibration operation to adjust read voltages used for determining stored data at the wordline (the array). The controller can track memory device degradation (e.g., the memory cells) over time by tracking instantaneous read level measurements over time, known as read level tracking. The controller executes the calibration operation to monitor an instantaneous read level measurement (also referred to as a read level measurement) for a shift (a change). In response to detecting the shift (also known as a read level shift), the controller can use the detected shift to identify new read voltages that should be used in future read operations of the array to compensate for changes in memory device performance characteristics. In some examples, the new read voltages are identified in response to the detected shift exceeding a shift threshold.

Accordingly, in response to detecting the read level shift indicative of a change in memory device performance (e.g., cell characteristic changes), the controller can recalibrate (e.g., adjust) the read voltages so that the data stored in the array can be correctly read during future read operations. If the controller does not adjust the read voltages that are used to read data from the memory devices, the controller will not read the stored data correctly, which leads to increased error rates and data corruption in the memory device.

In some examples, the controller uses bins for adjusting read voltages that are used to read data from the array. Each bin can include (identify) read voltages that can be used for reading different logic states from the array correctly. In some examples, each of the bins can be associated with or identify a trigger rate profile. The trigger rate profile for each bin can identify read voltages that are most likely to allow for the correct reading of logic states from the array. Thus, each bin's trigger rate profile reflects the tuned read voltages for the array (or the cells of the array) currently assigned to that bin.

The controller can use the read level measurement to selectively assign the array to a corresponding bin of the bins. Using the assigned bin, new read voltages for that assigned bin can be generated by the controller in subsequent read operations so that the data stored at the array can be correctly interpreted (read). Thus, the new bins identify new read voltages that can be used to read (correctly) the data stored in the array in response to performance changes in the memory device. Accordingly, the controller can dynamically assign the array to a bin to compensate for memory device performance changes so that data stored in the array can continue to be read correctly.

The read level measurement can decrease (change) linearly. However, the external factors, such as noise and variations (e.g., temperature variations) as the memory device operates, prevents the read level measurement from changing linearly. The external factors introduce variability (fluctuation) and cause the read level measurement to fluctuate over time, resulting in a non-linear read level shift.

A non-linear read level shift can cause the controller to assign the array to an incorrect bin. For instance, if noise causes the array (e.g., one or more cells of the array) assigned to Bin 3 (1.4V-1.6V) to momentarily conduct at 1.7V, the controller can mistakenly assign the array to Bin 4, where a correct bin is still Bin 3. Since Bin 4 has a different trigger rate profile than Bin 3, this reassignment (or assignment) results in a trigger rate profile with a higher error rate being used for the array. In some instances, until a subsequent calibration, incorrect read voltages are used to read data from the array based on the trigger rate profile with the higher error rate, which can result in misreads. Consequently, the controller applies read voltages less suited for a cell's actual state (e.g., behavioral state), leading to a higher likelihood of read errors. As such, future read operations would apply the wrong read voltages, causing inaccuracies in reading the stored data until the subsequent calibration updates to a newer (more appropriate) trigger rate profile.

According to the examples herein, a rolling average read level tracking technique is described that can be used in a read level calibration. The technique of the present disclosure uses a rolling average instantaneous read level measurement (also referred to as a rolling average measurement or RM). This technique curtails variations in instantaneous read level measurements caused by external factors, such as noise and variations (e.g., temperature variations), which can otherwise lead to inaccurate bin assignments. By smoothing out these variations, the rolling average measurement improves a precision of bin assignment (also referred to as bin level assignment).

The rolling average measurement can be computed based on a previous rolling average read level measurement and a current instantaneous read level measurement (also referred to herein as a current read level measurement), effectively averaging data over time. This averaging of data creates a stable and accurate representation of a memory device's behavior (e.g., cell characteristics), reducing the effects of short-term noise or anomalies as compared to prior approaches that use a one-time measurement approach (e.g., only the current read level measurement) for bin assignment. Furthermore, using the rolling average measurement for bin assignment results in an accurate and consistent read level calibration compared to the prior approaches. Using the rolling average read level tracking technique for read level calibration ensures that an appropriate trigger rate profile is selected for reading data from the memory cells, thus reducing a likelihood of read errors while increasing an overall reliability and efficiency of memory operations.

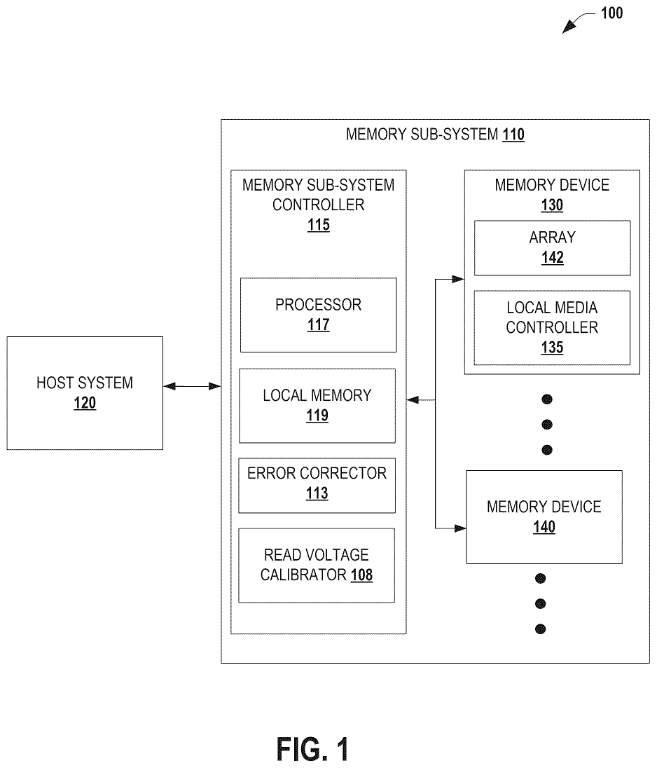

FIG. 1 illustrates an example computing system 100 that includes a memory subsystem 110 in accordance with some examples of the present disclosure. The memory subsystem 110 can include media, such as one or more volatile memory devices (e.g., memory device 140), one or more non-volatile memory devices (e.g., memory device 130), or a combination of such. The memory sub-system 110 can be a storage device, a memory module or a hybrid of a storage device and a memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card and a hard disk drive (HDD). Examples of memory modules include a dual in-line memory module (DIMM), a small outline DIMM (SO-DIMM) and various types of non-volatile dual in-line memory modules (NVDIMMs).

The system 100 can be a computing device such as a desktop computer, laptop computer, network server, mobile device, a vehicle (e.g., airplane, drone, train, automobile or other conveyance), Internet of Things (IoT) enabled device, embedded computer (e.g., one included in a vehicle, industrial equipment or a networked commercial device) or such computing device that includes memory and a processing device. The system 100 can include a host system 120 that is coupled to one or more memory sub-systems 110. In some examples, the host system 120 is coupled to different types of the memory sub-system 110. FIG. 1 illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller) and a storage protocol controller (e.g., PCIe controller, SATA controller, CXL controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a compute express link (CXL) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), Open NAND Flash Interface (ONFI), Double Data Rate (DDR), Low Power Double Data Rate (LPDDR), or any other interface, or any other interface.

The physical host interface can be used to transmit data between the host system 120 and the memory sub-system 110. The host system 120 can further utilize an NVM Express (NVMe) interface to access the memory components (e.g., memory device(s) 130) when the memory sub-system 110 is coupled with the host system 120 by the physical host interface (e.g., a PCIe or CXL bus). The physical host interface can provide an interface for passing control, address, data and other signals between the memory sub-system 110 and the host system 120. FIG. 1 illustrates a memory sub-system 110 as an example. In general, the host system 120 can access multiple memory sub-systems via a same communication connection, multiple separate communication connections and/or a combination of communication connections.

The memory device 130 and the memory device 140 are implemented as non-transitory computer readable media. The memory device 130 and the memory device 140 can include any combination of the different types of non-volatile memory devices and/or volatile memory devices. The volatile memory devices (e.g., the memory device 140) can be, but are not limited to, random access memory (RAM), such as dynamic random access memory (DRAM) and synchronous dynamic random access memory (SDRAM).

Some examples of non-volatile memory devices (e.g., memory device(s) 130) include NAND type flash memory and write-in-place memory, such as three-dimensional cross-point (“3D cross-point”) memory. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

In some examples, a non-volatile memory device is a package of one or more dies. The dies in the packages can be assigned to one or more channels for communicating with the controller 115. Each die can consist of one or more planes. Planes can be grouped into logic units (LUN). For some types of non-volatile memory devices (e.g., NAND memory devices), each plane consists of a set of physical blocks, which are groups of memory cells to store data. A cell is an electronic circuit that stores information.

Each of the memory device(s) 130 include one or more arrays of memory cells. One type of memory cell, for example, SLC can store one bit per cell. Other types of memory cells, such as MLCs, TLCs, QLCs and PLCs or higher, can store multiple bits per cell. In some examples, each of the memory devices 130 can include one or more arrays of memory cells such as SLCs, MLCs, TLCs, QLCs, PLCs or some combination thereof. In some examples, a particular memory device can include an SLC portion, an MLC portion, a TLC portion, a QLC portion and/or PLC portion of memory cells. Depending on a cell type, a cell can store one or more bits of binary information and has various logic states that correlate to a number of bits being stored. The logic states can be represented by binary values, such as “0” and “1”, or combinations of such values. The memory cells of the memory devices 130 can be grouped as pages that can refer to a logical unit of the memory device used to store data. In some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), not-OR (NOR) flash memory, electrically erasable programmable read-only memory (EEPROM), etc.

A memory sub-system controller 115 (or controller 115 for simplicity) communicates with the memory device(s) 130 to perform operations such as reading data, writing data or erasing data at the memory devices 130 and other such operations. The memory sub-system controller 115 can include hardware such as one or more integrated circuits and/or discrete components, a buffer memory or some combination thereof. The hardware can include a digital circuitry with dedicated (e.g., hard-coded) logic to perform the operations described herein. The memory sub-system controller 115 can be a microcontroller, special purpose logic circuitry (e.g., a field programmable gate array (FPGA), an application specific integrated circuit (ASIC), etc.) or other suitable processor.

The memory sub-system controller 115 can include a processing device, which includes one or more processors (e.g., the processor 117), configured to execute instructions stored in a local memory 119. In the illustrated example, the local memory 119 of the memory sub-system controller 115 includes an embedded memory configured to store instructions for performing various processes, operations, logic flows and routines that control operation of the memory sub-system 110, including handling communications between the memory sub-system 110 and the host system 120. The local memory 119 is a non-transitory computer-readable medium.

In some examples, the local memory 119 can include memory registers storing memory pointers, fetched data, etc. The local memory 119 can also include read-only memory (ROM) for storing micro-code. While the example memory sub-system 110 in FIG. 1 has been illustrated as including the memory sub-system controller 115, in another example, a memory sub-system 110 does not include a memory sub-system controller 115 and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and ECC operations, encryption operations, caching operations and address translations between a logical address (e.g., a logical block address (LBA), namespace) and a physical address (e.g., physical block address) that are associated with the memory devices 130.

The memory sub-system controller 115, for example, may employ a Flash Translation Layer (FTL) to translate logical addresses to corresponding physical memory addresses, which can be stored in one or more FTL mapping tables. In some instances, the FTL mapping table can be referred to as a logical-to-physical (L2P) mapping table storing L2P mapping information. The memory sub-system controller 115 can further include host interface circuitry to communicate with the host system 120 via the physical host interface. The host interface circuitry can convert the commands received from the host system into command instructions to access the memory devices 130 as well as convert responses associated with the memory devices 130 into information for the host system 120.

The memory sub-system 110 can also include additional circuitry or components that are not illustrated. For example, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some examples, the memory devices 130 include local media controllers 135 that operate in concert with the memory sub-system controller 115 to execute operations on one or more memory cells of the memory devices 130. An external controller (e.g., the memory sub-system controller 115) can externally manage the memory device 130 (e.g., perform media management operations on the memory device 130). In some examples, the memory sub-system 110 is a managed memory device, which is a raw memory device 130 having control logic (e.g., local media controller 135) on the die and a controller (e.g., the memory sub-system controller 115) for media management within the same memory device package. An example of a managed memory device is a managed NAND (MNAND) device.

The memory device 130 and the memory device 140 are structured to include wordlines. Wordlines are addressable wiring lines that connect and control a row of memory cells in the memory device 130 and the memory device 140, referred to herein as an array 142. Each wordline addresses the cells in a corresponding row contemporaneously (the array 142), enabling operations such as reading, writing and erasing data. The memory device 130 and the memory device 140 can be organized into an array of cells arranged in blocks, with each block containing multiple pages. The cells in a page are connected by these wordlines horizontally and bitlines vertically, forming a grid-like structure that allows for efficient data access and management.

In some examples, the memory sub-system 110 includes an error-corrector 113 that executes an error-handling of data read from the memory device 130 and/or the memory device 140. In operation, the host system 120 manages and controls the flow of data between itself and the memory sub-system 110, ensuring efficient data storage and retrieval operations. More generally, the host system 120 employs the memory sub-system 110 to write data to and read data from the memory sub-system 110. For instance, the host system 120 processes these requests for reading and/or writing data by interacting with the memory sub-system 110, managing the flow of data to and from the memory device 130 and/or the memory device 140 within the memory sub-system 110. This reading and writing of data enables operation of computing systems where data access and management are needed.

For example, in some instances, the controller 115 can retrieve or receive data from the memory device 130 or the memory device 140. The data can be stored in the array 142 of the memory device 130 or the memory device 140. The controller 115 can retrieve the data in response to a read command from the host system 120, in some instances. This read command can correspond to a request for the data stored within the memory sub-system 110 and thus in some instances the data can be referred to as read data.

The controller 115 can access a block of memory cells (the array 142) in the memory device 130 or memory device 140, where the requested data resides. The data can be stored in a form of a codeword, which includes both original data (also referred to as user data) and additional parity bits, which can be used for error correction. These parity bits can be generated during an encoding process of the original data, using an ECC such as LDPC codes and are stored alongside the original data in the memory device 130 or the memory device 140. Parity bits are additional bits added to the original data to help detect and correct errors.

In some instances, the controller 115 can implement an encoding algorithm (e.g., an ECC algorithm) to generate the codeword. The controller 115 retrieves or receives the codeword from the array 142 corresponding to reading the data in response to a read operation. For example, the controller 115 can retrieve the codeword from a NAND memory device, which can be represented by the memory device 130 or the memory device 140 using a NAND read operation.

In some examples, the memory device 130 or 140 can perform read operations, such as hard reads (1H) to provide hard data, which includes a combination of hard bits. A “hard bit” in this context is a binary read of data where each bit is read and immediately interpreted as either a “0” or a “1”, based on a fixed threshold, a Hard Read Position (HRP) threshold, which is based on a distribution of threshold voltages of the memory device. For example, in NAND flash memory, a voltage level above the HRP might be interpreted as “0”, and below the HRP as “1”.

For example, during the read operation, the controller 115 applies one or more read voltages to a wordline for the array 142. Each cell of the array 142 can be coupled to the wordline and can be accessed or manipulated based on a read voltage. The wordline affects all cells connected to the wordline simultaneously, where each cell can store a logic state. A size of the logic state can be based on a cell type, for example, single level cells can store one bit to represent a logic state, whereas higher-order cells can store several bits to represent a logic state.

The logic state stored in each memory cell of the array 142 can depend on an amount of electrical charge (the stored charge) programmed into the cell's gate (e.g., a floating gate), such as during a write operation. Each level of charge in a cell can correspond to different logic states, which can represent multiple bits in higher-order cell configurations. An amount of electrical charge (e.g., a number of electrons) in a gate influences a voltage threshold of the cell.

For example, the controller 115 can determine which wordline needs to be accessed based on an address of the data being requested. The controller 115 can send a command to activate a particular wordline where the array 142 is located in the memory device 130 or the memory device 140. In some instances, wordline drivers can be activated by the controller 115 in response to a control voltage being applied to the gates of all cells of the array 142 in that wordline, making the array 142 ready to be read. As an example, if the memory cells are SLCs, a single read voltage can be used to distinguish between the two states.

For example, when reading the data (e.g., the codeword) from the array 142, the controller 115 applies a set of read voltages to the wordline to determine the codeword being stored. The set of read voltages can include a sequence of read voltages that can be systematically applied to the array 142. These read voltages progressively increase from a minimum to a maximum read voltage level, each probing different potential charge states stored within the array 142.

As each read voltage is applied, one or more sense amplifiers connected to the bitline can detect whether current flows through one or more cells of the array 142 at an applied read voltage. In some examples, the set of read voltages are HRP thresholds that are applied to the wordline and thus the read data is the hard data (the codeword). For example, if a cell's charge allows the cell to exceed the HRP threshold (e.g., a lower threshold state), the cell conducts current, and the one or more sense amplifiers detects this, interpreting the state as “1”. If a cell's charge does not allow the cell to exceed the HRP threshold (e.g., a higher threshold state), the cell does not conduct current, and the one or more sense amplifiers detects no current, interpreting the state as “0”.

Thus, as each read voltage is applied, the memory controller 115 records the output from the array 142 to provide read voltage response data 224, as described herein. The read voltage response data 224 can indicate a number of cells that conducted electricity (e.g., output a signal indicative of a stored logic state) at each read voltage level.

Applying an incorrect read voltage to the array 142 can result in a misread of stored data therein, such as the codeword. Misreads in memory cells (or the array 142) often stem from changes in performance characteristics of the memory device, such as from degradation. Memory device performance is influenced by changes in cell attributes (or characteristics) over time. Cell changes can include shifts in cell threshold voltages due to cell aging and wear from repeated write/delete cycles, which affect how the array 142 responds to applied read voltages.

To curtail misreads resulting from changes in cell characteristics, the controller 115 calibrates (adjusts) the read voltages over time in response to memory device performance changes so that the data can be interpreted (read) correctly from the array 142 during a read operation. Calibration involves adjusting the read voltages based on ongoing assessments of memory device behavior (e.g., cell behavior due to aging) of the array 142. For example, the controller 115 can include a read voltage calibrator 108 (for simplicity calibrator 108). In some examples, the error corrector 113 includes the calibrator 108. In yet further examples, the calibrator 108 includes the error corrector 113.

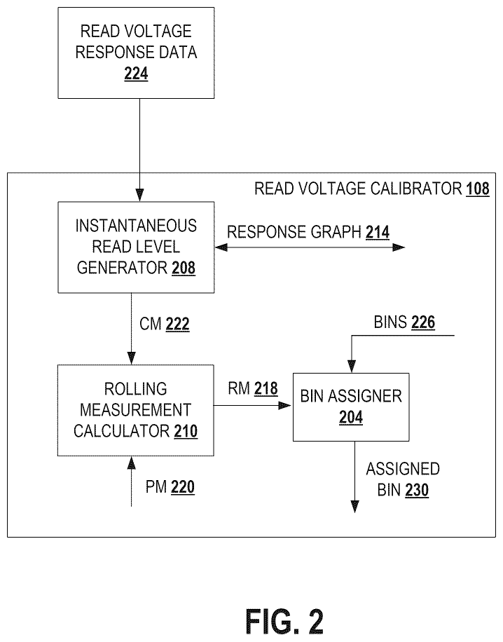

FIG. 2 illustrates an example of the error corrector 113 of FIG. 1. While the example of FIG. 2 illustrates the calibrator 108 as being implemented as part of the error corrector 113, in other examples, the calibrator 108 could be implemented as a stand element or combination of elements (e.g., modules). The calibrator 108 can be implemented using one or more modules, shown in block form in the drawings. The one or more modules can be in software or hardware form, or a combination thereof. In some examples, one or more functions of the calibrator 108 can be implemented as machine readable instructions for execution by the controller 115, as shown in FIG. 1.

The controller 115 uses the calibrator 108 to dynamically adjust read voltages for reading data from the array 142 based on performance characteristics of the memory device 130 or 140. The performance characteristics of the memory device 130 or 140 can change because of changes in cell characteristics of cells of the array 142 and/or from other factors, referred to as external factors, such as noise and variations (e.g., temperature variations). The controller 115 can use the calibrator 108 to track the degradation of the memory device 130 or 140 over time to make changes to the read voltages so that the stored data can be accurately read from the array 142.

For example, the controller 115 can use the calibrator 108 to implement a calibration operation. The calibration operation can be implemented periodically as the memory device 130 or 140 operates. During each calibration operation (calibration process), the controller 115 can compute a rolling average instantaneous read level measurement 218 (also referred to as a rolling average read level measurement 218, or RM 218). The RM 218 can be used to identify new read voltages to compensate for changes in operational performance of the memory device 130 or 140 from internal and external factors to allow the memory device 130 or 140 to read the stored data correctly from the array 142. The controller 115 determines the RM 218 based on a previous rolling average instantaneous read level measurement 220 (also referred to as a previous rolling average read level measurement or PM 220) and a current instantaneous read level measurement 222 (also referred to as a current read level measurement or CM 222). The RM 218, the PM 220 and the CM 222 can be stored in the local memory 119 of FIG. 1.

For example, to determine an instantaneous read level measurement, such as during calibration, the controller 115 can apply read voltages to the wordline and monitor (record) a number of cells of the array 142 that conduct electricity at each read voltage to generate read voltage response data 224, as shown in FIG. 2. The read voltage response data 224 can be stored in the local memory 119. During the calibration, the array 142 can store data, such as the codeword. The controller 115 can use the read voltage response data 224 to determine the instantaneous read level measurement, such as the CM 222, as described herein.

The read voltages applied can cover a range from lowest to the highest possible charge states (logic states) that could be stored in the array 142. As each read voltage is applied to the array 142, the controller 115 can monitor a number of cells of the array 142 that conduct electricity at that read voltage to provide the read voltage response data 224. Each cell conducts electricity when an applied voltage (a unique read voltage) exceeds a threshold voltage for that cell. The cell conducting corresponds to reading the stored state. The read voltage response data 224 can identify read voltages at which one or more cells of the array 142 responded and the number of cells that responded at each unique read voltage. Thus, each read voltage at which one or more cells of the array 142 responded can be indicative of a logic state being stored by that cell.

The calibrator 108 includes an instantaneous read level generator 208 (for simplicity generator 208). The generator 208 can record a distribution of logic states that can be stored in the array, which can be represented as a response graph 214 (referred to herein as graph 214). The generator 208 can store the distribution recording in the memory 119. The generator 108 can record the distribution of the logic states based on the read voltage response data 224. For example, the generator 208 can analyze (evaluate) the graph 214 (the distribution recording) to determine the CM 222, as shown in FIG. 2. As described herein, the CM 222 can shift over time (referred to as a read level shift) because of changes in memory device performance, which can be influenced by the external factors, as described herein.

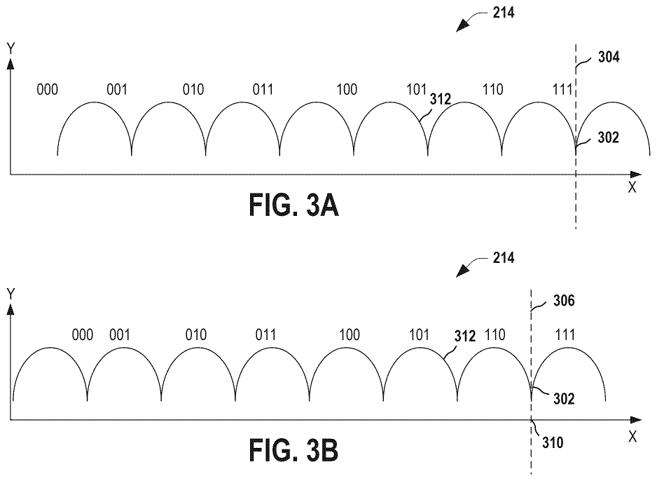

FIG. 3A is an example of the graph 214 of FIG. 2 without a read level shift (e.g., an initial state) corresponding to a distribution of logic states without a read level shift. FIG. 3B is an example of the graph 214 with a read level shift (e.g., after a period of time) corresponding to a distribution of logic states with a read level shift. An x-axis of the graph 214 can represent a read level, in volts (V) and a y-axis of the graph 214 in FIGS. 3A-3B can represent a number of memory cells of the array 142 with the corresponding read level.

The graph 214, as shown in FIGS. 3A-3B includes a distribution 312 (also known as a distribution curve 312), wherein each portion of the distribution curve (referred to as a distribution curve portion or distribution portion) can represent a distribution of read levels (voltages) for a given logic state of a number of logic states that could be stored in the array 142. Each distribution curve portion for each logic state of the distribution curve 312 can indicate a number of cells that responded at one or more read voltages that was applied to the array 142. Thus, each distribution curve portion for each logic state of the distribution curve 312 can identify a number of cells of the array 142 that had conducted at unique read voltages (a range of read voltages) that resulted in those cells conducting to provide a given logic state.

In FIGS. 3A-3B, the distribution curve portion for each logic state that can be stored by the array 142 is identified by that logic state and thus the graph 214 includes distribution curve portions 000, 001, 010, 011, 100, 101, 110, and 111. In the examples herein, the array 142 includes TLCs and thus can store eight different logic states, which multiple read levels (read voltages) can be used to correctly read potential logic states that could be stored in array 142. Thus, the examples of FIGS. 3A-3B illustrates eight distribution curve portions, one for each potential logic state that could be in the array 142 (in a TLC configuration). In other examples, the array 142 can include cells of a different type, and the distribution curve 312 can include more or less distribution curve portions. For example, if the array 142 includes MLCs, the graph 214 can include a distribution curve with four distribution curve portions for each possible logic state that could be stored in the array 142.

In some examples, the controller 115 uses a programming algorithm to tune the reliability and lifespan of the array 142 so that there is an about even distribution of wear across the array 142. The controller 115 can place data, which can be facilitated by ECC, to spread data uniformly across the array 142 to prevent any particular logic state from being favored. Such uniform distribution of data enables the memory device 130 or 140 to maintain a balanced wear and enhances an overall durability of the memory device 130 or 140.

Because the controller 115 attempts to evenly distribute the wear across the array 142 there can be about an equal distribution of logic states that could be stored by the array 142. Thus, by ensuring no single logic state is predominant, results in a scenario where each state from 000 to 111 for a TLC array memory configuration that has an equal probability of being written to any given cell of the array 142. This randomization can result in the distribution curve 312, as shown in FIGS. 3A-3B.

Each distribution curve portion can be bell-shaped or Gaussian and centered around a read level at which a greatest number of cells responded, known as a peak. A height (peak) of each distribution curve portion of the distribution curve 312 at a given read level is associated with the greatest number of cells that responded at that particular read level (read voltage). For example, a peak of the distribution curve portion 111 is associated with a read level at which a greatest number of cells for that logic state conducted, reflecting a common charge state (e.g., holding the same logic state).

While the graph 214 in examples of FIGS. 3A-3B illustrate distribution curve portions with similar peaks, in other examples, the distribution curve portions can have different heights and/or widths. A read level as used herein refers to a voltage (read voltage) that is applied to an array during a read operation to read data (e.g., a codeword) stored in the array. A correct setting of the read level is needed for accurately reading the data stored in the array 142, so that memory cell's threshold voltage is correctly identified, preventing data misinterpretation and errors.

The height and/or width of one or more distribution curve portions of the distribution curve 312 can vary based on one or more factors, such as due to variations in manufacturing processes and operational conditions of the memory device 130 or 140 (e.g., the array 142). For example, variations in manufacturing processes can cause differences in memory cell characteristics, affecting their charge storage capabilities and, consequently, their response behaviors. Operational conditions such as temperature and aging (e.g., a wear and tear of the cells of the array 142) can alter the charge retention and leakage behaviors of the cells, leading to shifts and changes in heights and widths of the distribution curve portions.

Furthermore, the distribution curve 312 (and thus distribution curve portions) can shift due to changes in threshold voltage levels of the memory cells of the array 142 over time, which can be caused by internal and/or external factors, such as cell aging, charge trapping, and temperature variations, for example. For instance, over time, repeated use (writing and erasing cycles) of the array 142 can lead to physical degradation, which can shift a threshold voltage higher or lower for the array 142, such that different read voltages are needed so that the data can be accurately read from the array 142.

Cell threshold voltage change over time can cause one or more of the distribution curve portions (or the distribution curve 312) to shift, which indicates a change in the threshold voltage that may be needed to read data from the array 142. In some instances, changes in temperature can affect electronic characteristics of the memory cells of the array 142, influencing how such circuits store and release charge. Higher temperatures can lower the threshold voltages, causing the one or more distribution curve portions (or the distribution curve 312) to shift to the left, while lower temperatures might have the opposite effect and cause these distribution curve portions to shift to the right.

By way of example, for simplicity purposes, FIG. 3B illustrates a shift of the distribution curve portion 110 in FIG. 3A to the left, such that a valley 302 between the distribution curve portions 110 and 111 shifts to the left. Thus, in some instances, the distribution curve portions 000, 001, 010, 011, 100, 101, 110 and 111 can shift to either to the left or to the right based on the internal and/or external factors that affect memory device performance. The shift of the distribution curve portion 110 to the left can result in incorrect read voltages (levels) being used for reading data from the array, which can result incorrect cell response behavior, which leads to an increase error rate at the memory device 130 or 140.

The generator 208 can be programmed to identify the shift of the valley 302 (e.g., a seventh valley) between the distribution curve portions 110 and 111 for further processing, as described herein. Thus, in some examples, the generator 208 (the controller 115) can identify a valley (the valley 302) between a penultimate distribution curve portion (the distribution curve portion 110) and a last distribution curve portion 111 of the distribution curve 312. In some instances, the valley 302 can be referred to as a select valley 302 as the generator 208 is programmed to search for this valley (in some instances among a number of valleys) on the graph 214. For example, the generator 208 can identify the valley 302 between the distribution curve portions 110 and 111 by computing a local minimum. A valley as used herein can refer to a point where a difference between two distribution curve portions is smallest. In some instances, the valley 302 is referred to as a reference point as the valley 302 is used to identify a read level (voltage) 310.

The generator 208 determines a valley position 304 of the valley 302 in the graph 214, as shown in FIG. 3A, which can correspond to a given read level. When the distribution curve portion 110 shifts to the left, the valley 302 shifts to the left, as shown in FIG. 3B. The generator 208 calculates a new local minimum for the valley 302 after the shift between the two distribution curve portions 110 and 111 and in response to calculating the new local minimum determines an updated valley position 306 for the valley 302, which can correspond to the read level 310, as shown in FIG. 3B. Thus, as the distribution curve 302 shifts to the left or the right, the valley 302 (e.g., the local minimum) is tracked to detect a valley shift (or change) based on valley position information. For example, the controller 115 can track a shift of a value of the read level 310 over time to detect the valley shift.

The generator 208 can evaluate the valley positions 304 and 306 (or the value of the read level 310) over time to detect the valley shift. In some examples, the valley shift is compared to a valley shift threshold, and the valley shift is detected if a difference between the valley positions 304 and 306 is greater than the valley shift threshold. In response to detecting the valley shift, the generator 208 can use a new valley location (the valley position 306) for the valley 302 to identify the read level 310, as shown in FIG. 3B.

The read level 310 associated with the valley position 306 of the valley 302, as shown in FIG. 3B, can be referred to as an instantaneous read level measurement (in some instances referred to simply as instantaneous measurement). The read level 310 is “instantaneous” because this value is measured (determined) at an instance in time and can be used to reflect or represent a memory device's current performance state (e.g., level of degradation). The instantaneous measurement can be indicative of a health (e.g., degradation level) for a specific portion of the memory device (e.g., a specific wordline or block) or an entire memory device, depending on how the controller 115 is set to monitor the memory device 130 or 140.

The valley 302 can shift, which causes a change in a value of the read level 310, in response to changes in memory device performance, which can be caused by external factors, such as noise and variations, as described herein. For example, the controller 115 can periodically (e.g., every minute, as an example) execute the calibration operation to execute a rolling average read level tracking technique to compute the RM 218. During read level tracking, the controller 115 tracks the valley 302 to track changes in the read level 310 over time for the memory device 130 or 140 according to the examples herein as the memory device 130 or 140 operates.

In some examples, the rolling average read level tracking technique can include one or more operations for recording distributions for each logic state that could be stored in the array 142 and bin assignment for providing an assigned bin 228, as described herein. In response to detecting a read level shift, the rolling average read level tracking technique computes the RM 218. The controller 115 uses the RM 218 to calibrate (or recalibrate) read voltages so that the data stored in the array 142 can be correctly read in future read operations as memory device performance changes.

Thus, according to the examples herein, the calibrator 108 can use the generator 208 to determine CM 222 based on the response graph 214. The CM 222 can be provided to a rolling measurement calculator 210 of the calibrator 108 (for simplicity calculator 210). The calculator 210 uses the CM 222 and the PM 220 (computed according to one or more examples described herein) to provide the RM 218.

For example, the calculator 210 can execute a rolling average operation to process the CM 222 and the PM 220 to compute the RM 218. In some examples, the rolling average operation is a simple moving average (SMA) operation, in other examples, an exponential moving average (EMA) operation, in yet other examples, a weighted moving average (WMA) operation. For example, using the WMA operation, the calculator 210 can compute the RM 218 using an WMA expression:

$$R M = P M \times ( 1 - w ) + C M \times w , \qquad ( 1 )$$

wherein RM (e.g., the RM 218) is a rolling average read level measurement, PM is a previous rolling average read level measurement (e.g., the PM 220), CM is a current read level measurement (e.g., the CM 222), and w is a weight ranging from 0 and 1.

By way of further example, using the SMA operation, the calculator 210 can compute the RM 218 using an SMA expression:

$$R M = \frac{P R + C M}{n} , \qquad ( 2 )$$

wherein n is a number of calibration cycles.

In examples in which the calculator 210 uses the SMA expression a number of previous rolling average measurements (the PM 220) can be used, which each can be stored in the memory 119.

The calibrator 108 can include a bin assigner 204, as illustrated in FIG. 2. The bin assigner 204 can assign one or more bins from a set of bins 226 to the array 142 based on the RM 218. In some examples, the bins 226 are stored in the local memory 119. The bins 226 can be stored in a data structure (e.g., a table). Each bin of the bins 226 can include (identify) read voltages that can be used for reading different logic states stored in the array 142 correctly based on memory device performance characteristics (that is changes in these characteristics, as described herein). In some examples, each of the bins 226 can be associated with or identify a trigger rate profile. The trigger rate profile for each bin can identify read voltages that are most likely to allow for the correct reading of logic states from the array 142. Each trigger rate profile can be stored in the memory 119. In some examples, each bin includes a respective trigger rate profile.

Since each array assigned to different bins can require different read voltages for accurate data interpretation (depending on memory device degradation), each bin's trigger rate profile reflects tuned read voltage for that array (or group of cells) currently assigned to that bin. The term “group” as used herein can include one or more objects, such as one or more cells. Accordingly, each trigger rate profile associated with each bin provides a mapped set of read voltages that are most likely to yield correct data reads from the array 142.

As memory cells degrade, for example, due to wear and tear, their ability to retain charge changes, which in turn can alter the voltage thresholds needed to read them accurately. The bin assigner 204 dynamically adjusts bin assignments to compensate for these changes. This adaptation allows the controller 115 to continuously apply one or more correct read voltages to array 142, reducing a likelihood of read errors that could result from using outdated read levels.

The CM 222 can decrease (change) linearly over time. However, due to external factors, such as noise and variations (e.g., temperature variations) as the memory device 130 or 140 operates, prevent the CM 222 from changing linearly. The external factors introduce variability (fluctuations) and cause the CM 222 to fluctuate over time, resulting in a non-linear read level shift.

A non-linear read level shift can cause the controller 115 to assign the array 142 to an incorrect bin. To curtail or compensate for the noise and variations of the memory device 130 and 140 over time, the controller 115 uses a rolling average measurement, the RM 218, which factors in previous rolling average read level measurements (the PM 220) and the current read level measurement (the CM 222) in a read tracking level process (technique).

Accordingly, the controller 115 can assign one or more new bins from the bins 226 to the array 142 based on the RM 218 as memory device performance changes. The one or more new assigned bins (identified as the assigned bin 230 in FIG. 2) can specify new read voltages (through a respective trigger rate profile), which can be used by the controller 115 so that the data (the codeword) stored in the array 142 can be correctly read. The controller 115 can use the new read voltages to read the logic states from the array 142, for example, during the read operation. By reassigning the array 142 to a new bin based on the RM 218, the controller 115 can make (future) reads using read voltages that allow for interpreting the stored data in the array 142 correctly as cell's characteristics change.

During each calibration operation, the controller 115 can execute the calibrator 108 for making bin assignment changes (if any) based on the RM 218 that is provided during that calibration operation. After making one or more bin assignment, the calibrator 108 can alert or notify the controller 115 of any bin assignment changes for the array 142. Using an updated bin assignment for the array 142 or a trigger rate profile for the bin to which the array 142 has been assigned, the controller 115 can generate appropriate read voltages so that the logic states from the array 142 can be correctly interpreted as memory device performance changes.

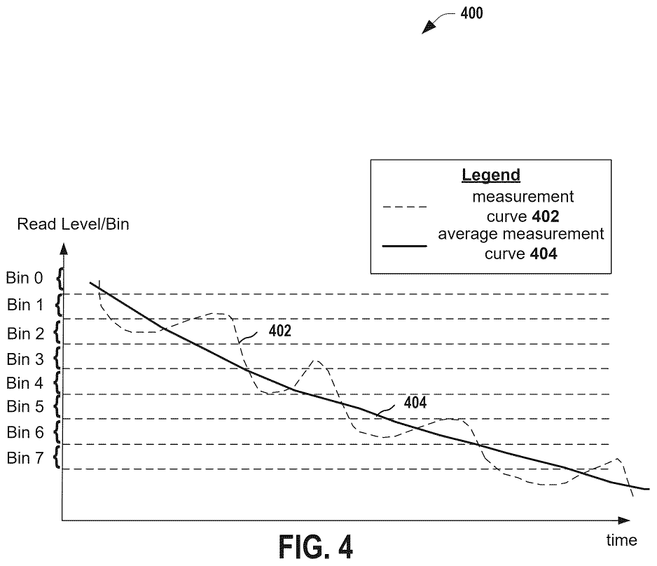

FIG. 4 illustrates a bin assignment graph 400 to provide a visual representation of bin assignment that can be executed by a controller of a memory device. An x-axis of the graph 400 can represent time and a y-axis of the graph 400 can represent read levels. The read levels can be associated with different bins in the graph 400, such as the bins 226. Thus, the graph 400 identifies eight bins corresponding to the bins 226, but in other examples, there could be more or less bins based on memory cell type. In the graph 400, each of the eight bins is identified as: Bin 0, Bin 1, Bin 2, Bin 3, Bin 4, Bin 5, Bin 6, and Bin 7. Each bin, labeled from Bin 0 to Bin 7, corresponds to specific read voltages (or a range of read voltages) that can be used to accurately interpret various logic states stored within the array 142.

The graph 400 includes an instantaneous measurement curve 402 (referred to herein as a measurement curve 402) representing an instantaneous read level measurement of a memory device as the memory device operates over time. The measurement curve 402 represents a read level shift over time for the memory device. Each point of the measurement curve 402 corresponds to an instantaneous read level measurement value at a moment in time that has been provided using an existing read level technique.

The graph 400 also includes a rolling average instantaneous measurement curve 404 (referred to herein as a rolling average measurement curve 404). The rolling average measurement curve 404 represents a rolling average instantaneous read level measurement computed over time for a memory device, such as the memory device 130 or 140, as illustrated in FIG. 1. Each point of the rolling average measurement curve 404 represents a computed rolling average measurement, such as the RM 218 computed at a distinct time during device operation (e.g., during a number of calibration operations) using a rolling average read level tracking technique of the present disclosure.

Memory devices are prone to performance characteristic changes due to external factors such as noise and variability, causing non-linear shifts in read levels over time, as depicted by the instantaneous measurement curve 402. This nonlinearity can lead to erroneous bin assignments. As shown in FIG. 4, the measurement curve 402 fluctuates over time and thus is non-linear.

For instance, if an array is initially assigned to Bin 3, a non-linear shift can result in a memory controller of the memory device to use read voltages for Bin 4 or Bin 2 for the array through an erroneous bin assignment. The memory controller can erroneously perceive this as a change in performance characteristics and reassign the array to Bin 4, leading to incorrect data interpretation and potential data corruption. A drop in read voltages below the lower threshold of Bin 3 could similarly result in an incorrect reassignment to Bin 2, despite the array still correctly corresponding to Bin 3's voltage range.

Employing a rolling average read level, as illustrated by rolling average measurement curve 404, smooths out the fluctuations found in the measurement curve 402 caused by noise and variations by averaging instantaneous read level measurements while incorporating both current and past measurements. The computed rolling average measurement (RM) stabilizes read level assessments, thereby reducing a likelihood of incorrect bin assignments. By continuously updating and using this rolling average, the controller 115 dynamically adapts to long-term shifts in performance characteristics without being misled by short-term noise or variations. This dynamic adjustment ensures that the controller accurately adapts to gradual changes in memory device performance, curtailing the impact of external factors.

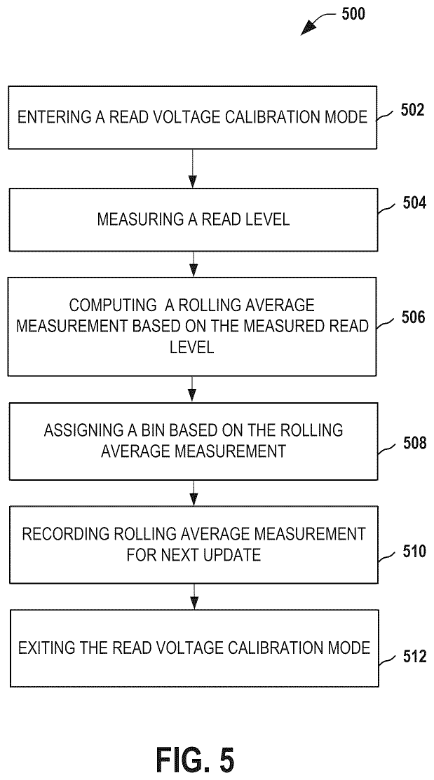

FIG. 5 illustrates a flowchart of an example method 500 for read voltage calibration at a memory device, such as the memory device 130 or 140 according to one or more examples of the present disclosure. The method 500 can be implemented, for example, by a controller, such as the memory sub-system controller 115 of FIG. 1. The method 500 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some examples, the method 500 is performed by the calibrator 108 of FIG. 2. Although shown in a particular sequence or order, unless otherwise specified, the order of the processes can be modified. Thus, the illustrated examples should be understood only as examples and the illustrated processes can be performed in a different order and some processes can be performed in parallel. Additionally, one or more processes can be omitted in various examples.

At block 502, the controller 115 initiates a read voltage calibration to enter a read voltage calibration mode to calibrate one or more read voltages used for reading data (e.g., a codeword) from the array 142 of the memory device 130 or 140. The controller 115 can periodically enter the read voltage calibration mode, in some instances, after a set of number of read/write cycles of the array 142. For example, the controller 115 can enter the read voltage calibration mode to periodically to determine whether read voltages being used at the memory device 130 or 140 need adjustment (calibration) to compensate for changes in memory device performance, for example, due to changes in cell characteristics or other factors, such as noise and variations (e.g., temperature variations).

At block 504, the controller 115 can measure a read level, for example, in response to initiating the read voltage calibration. For example, the controller 115 can use the read voltage response data 224 to determine a distribution of read voltages that can be used to read different logic states that could be stored in the array 142. In some examples, the controller 115 records the distribution of read voltages and thus computes the distribution curve 302, as shown in FIGS. 3A-3B. The controller 115 can measure (determine) a read level (the read level 310) based on the distribution for each logic states that could be stored in the array 142 according to the examples herein. The measured read level can correspond to the CM 222 (a current read level measurement).

At block 506, the controller 115 calculates a rolling average measurement corresponding to the RM 218 based on at least the measured read level. The rolling average measurement can be calculated based on the PM 220 and the CM 222 (the measured read level). The previous (prior) rolling average measurement (the PM 220) can be stored in the memory 119 and computed according to one or more examples as described herein. The controller 115 can retrieve from the memory 119 the PM 220 and the CM 222 and use a rolling average operation (as described herein) to process the CM 222 and the PM 220 to compute the RM 218.

At block 508, the controller 115 uses the computed rolling average measurement (the RM 218) for bin assignment. For example, the controller 115 assigns one or more bins from a number of bins, such as the bins 226 to array 142 of the memory device 130 or 140. Once assigned, the controller 115 uses the assigned bins and/or one or more associated trigger rate profiles to generate read voltages for interpreting logic states stored in the array 142, such as during a read operation to read stored data (e.g., a codeword).

At block 510, the controller 115 can record the computed rolling average measurement in the memory 119 as the previous rolling average measurement, which forms a basis for a subsequent rolling average measurement computation. At block 512, the controller 115 exits the read voltage calibration mode. In some examples, the controller 115 exits the read voltage calibration mode in response to recording the computed rolling average measurement in the memory 119. In some examples, the controller 115 exits the read voltage calibration mode in response to bin assignment and thus the method 500 can proceed from block 508 to block 512.

The controller 115 applies the newly calculated read voltages to the array 142 during subsequent read operations. This step involves updating the operational parameters of the memory subsystem 110 using the recalibrated read voltages derived based on the RM 218. By utilizing one or more newly assigned bins and corresponding trigger rate profiles, the controller 115 can adjust read operations to current conditions of the array 142 (or the memory device 130 or 140), accounting for any variations in performance characteristics.

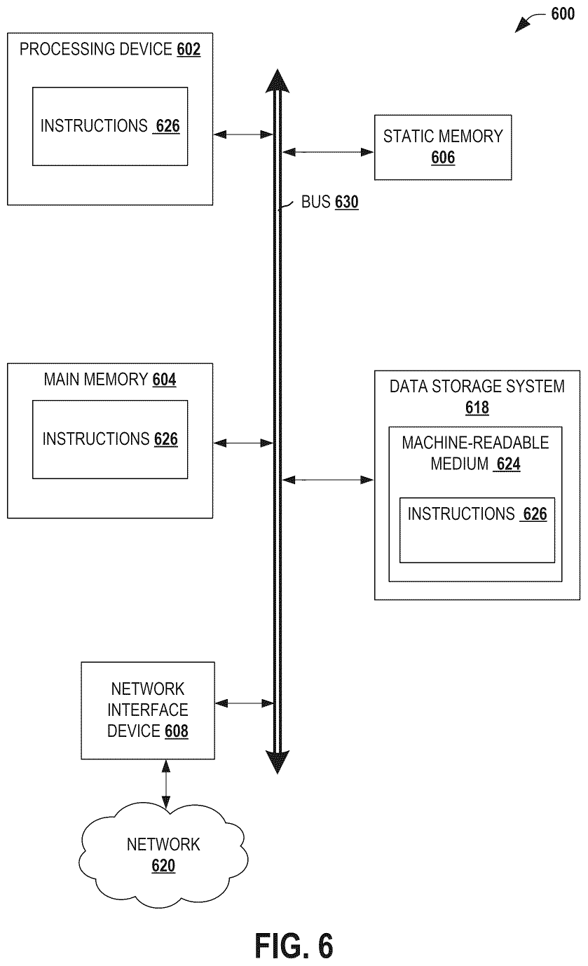

FIG. 6 illustrates an example machine of a computer system 600 (a machine) within which a set of instructions, for causing the machine to perform any one or more of the methodologies discussed herein, can be executed. In some examples, the computer system 600 corresponds to a host system (e.g., the host system 120 of FIG. 1) that includes, is coupled to, or utilizes a memory sub-system (e.g., the memory sub-system 110 of FIG. 1) or is used to perform the operations of a controller (e.g., to execute an operating system to perform operations corresponding to error corrector 113 of FIG. 1 and/or the calibrator 108). In other examples, the machine is connected (e.g., networked) to other machines in a LAN, an intranet, an extranet and/or the Internet. In various examples, the machine operates in the capacity of a server or a client machine in client-server network environment, as a peer machine in a peer-to-peer (or distributed) network environment or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge or any machine capable of executing a set of instructions (sequential or otherwise) that specify actions to be taken by that machine. In other examples, the machine may be a computer within an automotive, a data center, a smart factory or other industrial application. Further, while a single machine is illustrated, the term “machine” shall also be taken to include any collection of machines that individually or jointly execute a set (or multiple sets) of instructions to perform the methodologies discussed herein.

The example computer system 600 includes a processing device 602, a main memory 604 (e.g., read-only memory (ROM), flash memory, dynamic random access memory (DRAM) such as synchronous DRAM (SDRAM) or Rambus DRAM (RDRAM), etc.), a static memory 606 (e.g., flash memory, static random access memory (SRAM) or other non-transitory computer-readable media) and a data storage system 618, which communicate with each other via a bus 630.

The processing device 602 represents one or more general-purpose processing devices such as a microprocessor, a central processing unit, etc. More particularly, the processing device 602 can be a complex instruction set computing (CISC) microprocessor, reduced instruction set computing (RISC) microprocessor, very long instruction word (VLIW) microprocessor or a processor implementing other instruction sets or processors implementing a combination of instruction sets. In some examples, the processing device 602 is implemented with a special-purpose processing devices such as an application specific integrated circuit (ASIC), a field programmable gate array (FPGA), a digital signal processor (DSP), network processor, etc. The processing device 602 is configured to execute instructions 626 for performing the operations discussed herein. In some examples, the computer system 600 includes a network interface device 608 to communicate over the network 620.

The data storage system 618 includes a machine-readable storage medium 624 (also known as a computer-readable medium) that store sets of instructions 626 or software for executing the methodologies and/or functions described herein. The machine-readable storage medium 624 is a non-transitory medium. The instructions 626 can also reside, completely or at least partially, within the main memory 604 and/or within the processing device 602 during execution thereof by the computer system 600, the main memory 604 and the processing device 602 also constituting machine-readable storage media. The machine-readable storage medium 624, data storage system 618 and/or main memory 604 can correspond to the memory sub-system 110 of FIG. 1. Accordingly, the machine-readable storage medium 624, the data storage system 618 and/or the main memory 604 are examples of non-transitory computer-readable media.

In some examples, the instructions 626 include instructions to implement functionality corresponding to the error corrector 113 of FIG. 1. While the machine-readable storage medium 624 is shown in an example to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared and otherwise manipulated. It has proven convenient at times, principally for reasons of common usage, to refer to these signals as bits, values, elements, symbols, characters, terms, numbers, etc.

It is noted, however, that all of these and similar terms are to be associated with the appropriate physical quantities and are merely convenient labels applied to these quantities. This description can refer to the action and processes of a computer system, or similar electronic computing device, which manipulates and transforms data represented as physical (electronic) quantities within the computer system's registers and memories into other data similarly represented as physical quantities within the computer system memories or registers or other such information storage systems.

This description also relates to an apparatus for performing the operations herein. This apparatus can be specially constructed for the intended purposes or this apparatus can include a general purpose computer selectively activated or reconfigured by a computer program stored in the computer. Such a computer program can be stored in a computer readable storage medium, such as, but not limited to, any type of disk including floppy disks, optical disks, CD-ROMs, magnetic-optical disks, read-only memories (ROMs), random access memories (RAMs), EPROMs, EEPROMs, magnetic or optical cards or any type of media suitable for storing electronic instructions, each coupled to a computer system bus.

The algorithms and displays presented herein are not inherently related to any particular computer or other apparatus. Various general purpose systems can be used with programs in accordance with the descriptions herein, or it can prove convenient to construct a more specialized apparatus to perform the method. In addition, the present disclosure is not described with reference to any particular programming language. It will be appreciated that a variety of programming languages can be used to implement the teachings of the disclosure as described herein.

What have been described above are examples. It is, of course, not possible to describe every conceivable combination of components or methodologies, but one of ordinary skill in the art will recognize that many further combinations and permutations are possible. Accordingly, the disclosure is intended to embrace all such alterations, modifications and variations that fall within the scope of this application, including the appended claims. As used herein, the term “includes” means includes but not limited to, the term “including” means including but not limited to. The term “based on” means “based at least in part on”. Additionally, where the disclosure or claims recite “a,” “an,” “a first” or “another” element, or the equivalent thereof, it should be interpreted to include one or more than one such element, neither requiring nor excluding two or more such elements.

What is claimed is:

1. A method for calibration of read voltages in a memory device, comprising:
measuring, by a controller, a read level corresponding to a predetermined voltage applied to an array of the memory device;
computing, by the controller, a rolling average read level measurement based on the read level and a previously computed rolling average read level measurement; and
assigning, by the controller, the array to a respective bin of bins to identify one or more read voltages for use by the controller to read data from the array.

2. The method of claim 1, further comprising recording in memory the computed rolling average read level measurement for use in a subsequent rolling average read level measurement computation to replace the previously computed rolling average read level measurement.

3. The method of claim 1, wherein the measuring comprises:
computing, by the controller, read voltage response data indicating which memory cells of the array responded to read voltages applied to the array; and
recording, by the controller, a distribution for each logic state that could be stored by the array, the distribution being used to provide the read level.

4. The method of claim 3, wherein the distribution comprises a plurality of distribution portions and each distribution portion represents a corresponding logic state stored in the array.

5. The method of claim 4, wherein the measuring comprises identifying, by the controller, a valley between a penultimate distribution portion and a last distribution portion of the distribution.

6. The method of claim 5, wherein the measuring further comprises identifying, by the controller, a valley location for the valley corresponding to the read level.

7. The method of claim 6, wherein the measuring further comprises identifying, by the controller, the read level based on the valley location.

8. The method of claim 6, wherein the read level is a second read level, and the measuring further comprises:
determining, by the controller, a first read level for the valley;
detecting, by the controller, a valley shift based on a first read level and the second read level; and
identifying, by the controller, the second read level in response to the valley shift for computing the rolling average read level measurement.

9. The method of claim 1, wherein the rolling average read level measurement is computed using a rolling average operation comprising one of using a simple moving average, an exponential moving average, or a weighted moving average.

10. The method of claim 1, further comprising, initiating by the controller, a read voltage calibration to enter a read voltage calibration mode, wherein the read level is determined in response to the initiating.

11. The method of claim 9, wherein the array comprises an array of multi-bit memory cells.

12. The method of claim 1, wherein the memory device is a Not-AND (NAND) memory device.

13. A system for decoding data in a memory device, comprising:
a memory device;
a processing device coupled to the memory device, the processing device to perform operations comprising:
calibrating read voltages for reading data stored in the memory device based on a rolling average read level measurement that is computed based on a current read level measurement and one or more previously computed rolling average read level measurements; and
executing a read operation to decode the stored data in the memory device in response to the calibrating.

14. The system of claim 13, wherein the calibration comprises:
selecting an applied read voltage that was applied to an array of the memory device during the calibration corresponding to providing the current read level measurement;
computing the rolling average read level measurement based on the current read level measurement and the one or more previously computed rolling average read level measurements; and
assigning, by the controller, the array to a respective bin of bins to identify one or more read voltages for use by the processing device to decode the data stored in the array of the memory device.

15. The system of claim 14, wherein the calibration comprises recording the computed rolling average read level measurement in memory for use in a subsequent calibration as one of the one or more previously computed rolling average read level measurements.

16. The system of claim 14, wherein the memory device is a Not-AND (NAND) memory device.

17. The system of claim 14, wherein the processing device performs operations further comprising identifying a valley between a penultimate distribution portion and a last distribution curve of a recorded distribution for the array to identify the current read level measurement.

18. The system of claim 13, wherein the data is stored in an array of the memory device and the array comprises an array of multi-bit memory cells.

19. A non-transitory computer-readable storage medium comprising instructions that, when executed by a processing device, cause the processing device to perform operations comprising:
measuring a read level corresponding to a predetermined voltage applied to an array of a memory device;
computing a rolling average read level measurement based on the read level and a previously computed rolling average read level measurement; and
assigning the array to a respective bin of bins to identify one or more read voltages for reading data from the array.

20. The non-transitory computer-readable storage medium of claim 19, wherein the operations performed by the processing device further comprise recording the computed in memory rolling average read level measurement for use in a subsequent rolling average read level measurement computation as the previously computed rolling average read level measurement.
